(19) United States
(12) Patent Application Publication
(10) Pub. No.: US 2014/0059066 A1
(43) Pub. Date: Feb. 27, 2014

(54) SYSTEM AND METHOD FOR OBTAINING AND USING USER PHYSIOLOGICAL AND EMOTIONAL DATA

(71) Applicant: EmoPulse, Inc., Walnut, CA (US)

(72) Inventor: Nikolay Koloskov, Moscow (RU)

(73) Assignee: EmoPulse, Inc., Walnut, CA (US)

(21) Appl. No.: 13/975,141

(22) Filed: Aug. 23, 2013

Related U.S. Application Data
(60) Provisional application No. 61/693,024, filed on Aug. 24, 2012.
(60) Provisional application No. 61/804,151, filed on Mar. 21, 2013.

(51) Int. Cl. G06F 17/30; H05K 7/02

(52) U.S. Cl. CPC G06F 17/30017; H05K 7/02
USPC 707/758; 361/679.01

(57) ABSTRACT

A system and method for obtaining and using user physiological and emotional data is disclosed. One embodiment includes a wearable user device comprising a device body defining a first arm extending from a central body portion to a first-arm end and having an external first-arm face and an internal first-arm face on opposing sides of the first arm. The device may also include a second arm extending from the central body portion and a concave cavity defined by the first and second arm and the central portion and configured to be worn on an elongated part of a body. The device may also include a first display and a sensor array disposed on one or both of the internal first-arm and second-arm faces configured to contact the elongated part of a body when the user device is worn.

### CROSS-REFERENCE TO RELATED APPLICATIONS

This application claims the benefit of U.S. Provisional Application No. 61/693,024, filed Aug. 24, 2012 and claims the benefit of U.S. Provisional Application No. 61/804,151, filed Mar. 21, 2013, and these applications are hereby incorporated herein by reference in their entireties.

### BACKGROUND

Consumers of media content such as music and movies, or other entertainment or activities, desire experiences that they find enjoyable and that meet their personal tastes, moods and preferences. With an abundance of such content and activities available and a limited time for viewing, listening or experiencing, consumers must increasingly rely on recommendations from other users and from recommendation systems. For example, services like Pandora and Netflix have recommendation engines that suggest music and movies that a user may like based on user preferences.

However, users' preferences and desires change based on their moods and emotional states. Unfortunately, current recommendation systems have limited ability to accommodate such changes in preference or desire and users therefore receive a less than optimal experience.

In view of the foregoing, a need exists for improved systems and methods for obtaining and using user physiological and emotional data in an effort to overcome the aforementioned obstacles and deficiencies of conventional user recommendation systems.

### BRIEF DESCRIPTION OF THE DRAWINGS

FIG. 1a is an exemplary perspective drawing illustrating an embodiment of a wearable user device.

FIG. 1b is another exemplary perspective drawing illustrating the embodiment of the wearable user device of FIG. 1a.

FIG. 1c is another exemplary perspective drawing illustrating the embodiment of the wearable user device of FIGS. 1a and 1b.

FIG. 1d is another exemplary perspective drawing illustrating the embodiment of the wearable user device of FIGS. 1a, 1b and 1c being worn by a user.

FIG. 1e is another exemplary perspective drawing illustrating an embodiment of a wearable user device having rotatable portions.

FIG. 2 is an exemplary top-level drawing illustrating an embodiment of a device and server network that includes the wearable user device of FIGS. 1a-1e.

FIG. 3 is an exemplary data-flow diagram illustrating communications of an embodiment of generating a user physiological response profile.

FIG. 4 is an exemplary depiction of synchronized physiological data and media content data in accordance with an embodiment.

FIG. 5 is an exemplary data-flow diagram illustrating communications of an embodiment of generating a media response profile.

FIG. 6 is an exemplary data-flow diagram illustrating communications of another embodiment of generating a media response profile.

FIG. 7 is an exemplary data-flow diagram illustrating communications of a further embodiment of generating a media response profile.

FIG. 8 is an exemplary flow chart illustrating an embodiment of generating a media content recommendation.

It should be noted that the figures are not drawn to scale and that elements of similar structures or functions are generally represented by like reference numerals for illustrative purposes throughout the figures. It also should be noted that the figures are only intended to facilitate the description of the preferred embodiments. The figures do not illustrate every aspect of the described embodiments and do not limit the scope of the present disclosure.

### DETAILED DESCRIPTION OF THE PREFERRED EMBODIMENTS

Since currently-available user recommendation systems suffer from the deficiencies discussed above, a system and method for obtaining and using user physiological and emotional data can prove desirable and provide a basis for a wide range of applications, such as user recommendation systems. Additionally, such a system may have numerous additional applications and may include functionalities of a smart phone or the like. Emotional and physiological state data can also be used to improve user experience in the operation of a vehicle, health care maintenance, social networking, and the like. These results can be achieved, according to one embodiment disclosed herein, by a wearable user device 100 as illustrated in the following figures.

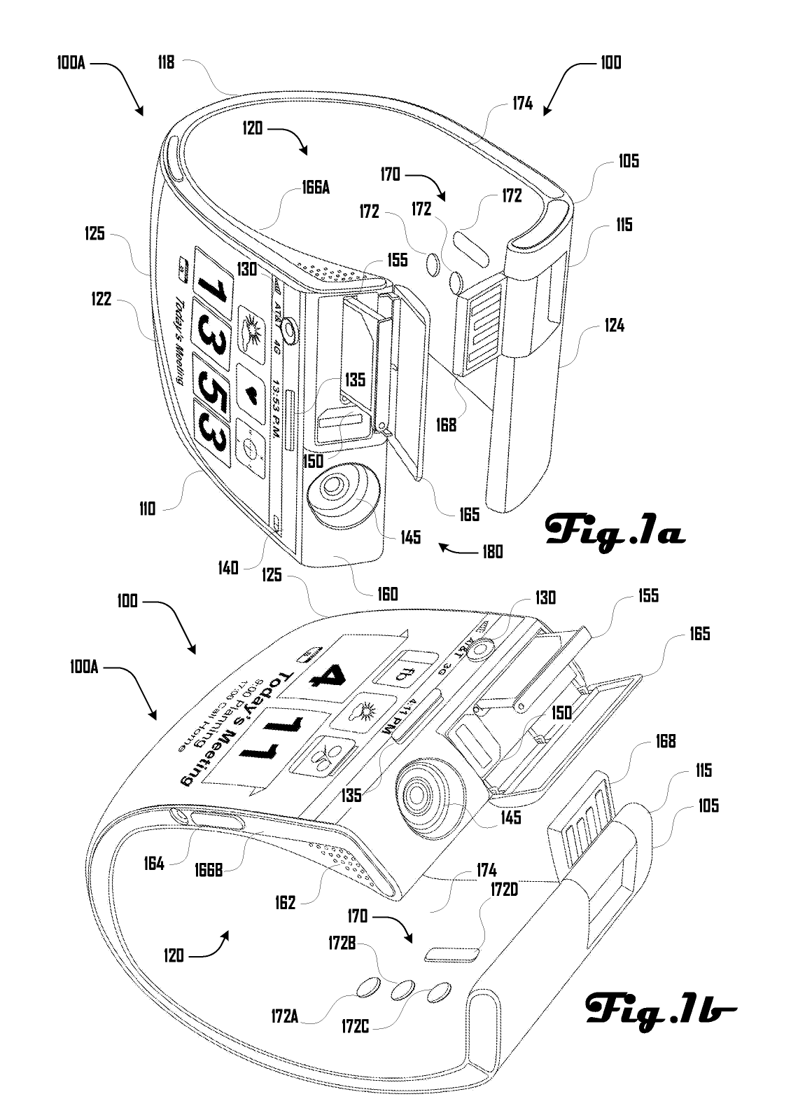

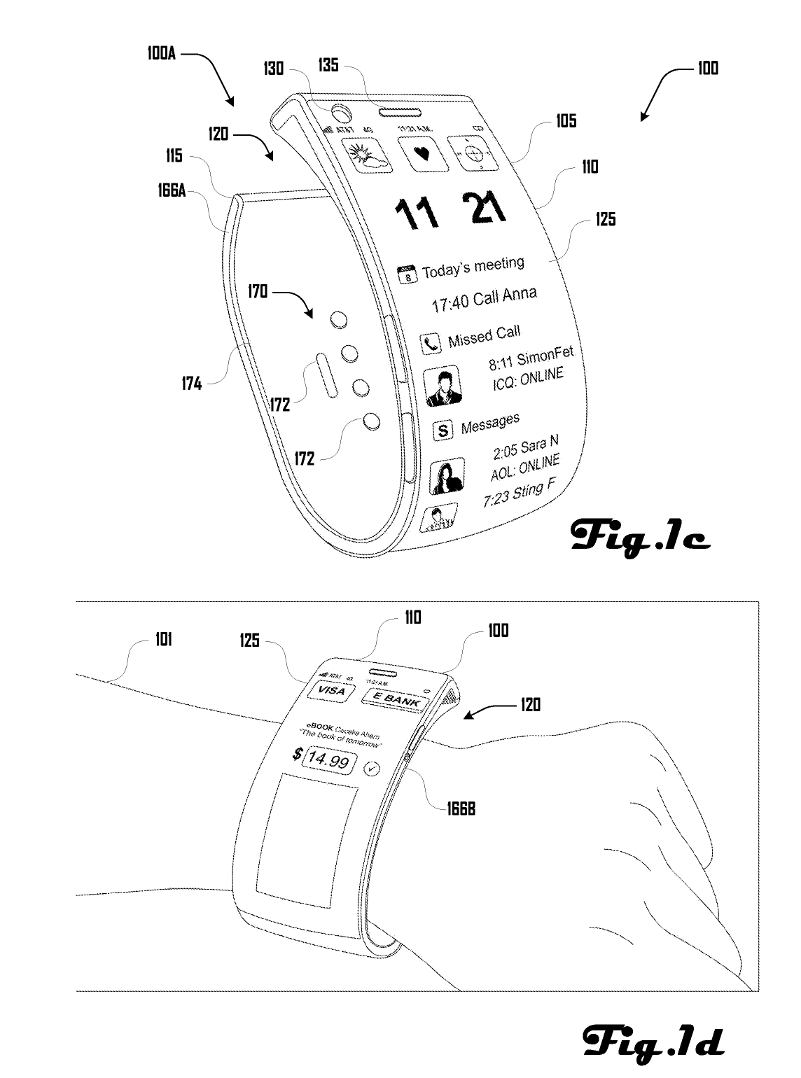

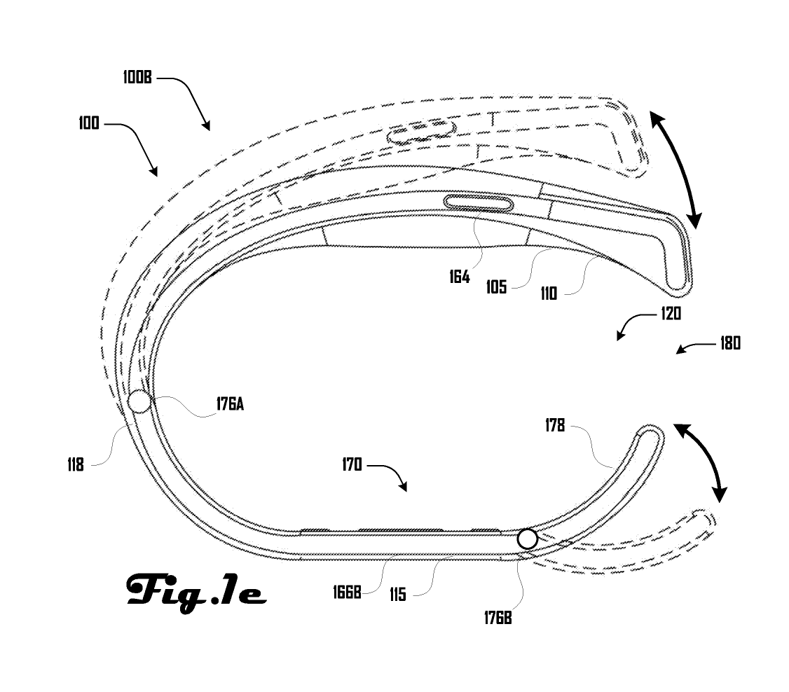

FIGS. 1a-1c depict one embodiment 100A of a wearable user device 100 and FIG. 1d depicts the wearable user device 100 being worn on the arm 101 of a user. The wearable user device 100 comprises a substantially C-shaped a device body 105 that includes a first and second arm 110, 115 that each extend from a central body portion 118 and collectively define a concave cavity 120 and a gap 180 between ends of the first and second arm 110, 115. The first and second arm 110, 115 comprise an external first-arm face 122 and an external second-arm face 124 respectively.

A first display 125 may be disposed on the external first-arm face 122. In some embodiments, the first display 125 may wrap around to the external second-arm face 124 or there may be a second display (not shown) disposed on the second-arm face 124. The display 125 may be any suitable display, and in one embodiment may be a flexible touch-screen display.

An external first-arm face camera 130 and an external first-arm face speaker 135 may be disposed on the first-arm face 122 at a first-arm end 140. Additionally, an end-face camera 145, an end-face port 150, and an end-face media-card slot 155 may be disposed at a first-arm end face 160, which may be substantially perpendicular to a portion of the first-arm face 122. The end-face port 150 and an end-face media-card slot 155 may be concealed below a hatch 165 that is rotatably coupled to a portion of the first-arm end 140. The device body 105 may also comprise a first and second side face 166A, 166B. Components such as a microphone 162 and button 164 may be disposed on the second side face 166B. Additionally, a communication plug 168 may be rotatably coupled at an end of the second arm 115.

The cavity 120 may be defined by an internal surface 174 of the first and second arm 110, 115. Various sensors and components may be disposed on the internal surface 174 and extend within the cavity 120. For example, there may be a sensor array 170 that includes a plurality of sensors 172 (e.g., a first, second, third and fourth sensors 172A, 172B, 172C, 172D).

FIG. 1e depicts an embodiment 110B of a wearable user device 100 that includes first and second hinges 176A, 176B that extend along the width of the device body 105. The first hinge 176A may be disposed at the central body portion 118 and be configured to rotatably couple the first and second arm 110, 115 such that the first and second arm 110, 115 are operable to rotate toward and away from each other. The movement of the first and second arm 110, 115 may increase and decrease the width of the gap 180. A second hinge 176B may be disposed along the length of a portion of the second arm 115 and define a rotatable second-arm tip 178. The tip 178 may also be configured to increase and decrease the width of the gap 180.

In various embodiments, the hinges 176A, 176B may be spring loaded and biased such that the device body 105 assumes a neutral collapsed configuration in the absence of force applied to the first and second arms 110, 115 or the tip 178. Such a biasing of the hinges 176A, 176B may be desirable because it may provide for a user to expand the gap 180, position the device 100 on the user's arm 101, and allow the arms 110, 115 and/or tip 178 to close on and hold the arm 101. Accordingly, the wearable user device 100 may be comfortably worn by users having arms 101 of various sizes.

In some embodiments, the hinges 176 may be motorized and the size of the user device 100 (i.e., the cavity 120 and gap 180) may be adjusted to a desired size, and such a configuration may be stored and automatically implemented when the user re-applies the device to his arm 101 after removing it.

In some embodiments, removing the user device 100 from the arm 101 may cause the device to be locked such that the functionalities of the user device 100 are reduced or limited, and access to data is reduced, limited or blocked. Opening the user device 100 may also be restricted in a locked configuration. The user device 100 may be unlocked via any suitable method including voice password, typed password, a pin, or the like. Retinal, fingerprint or facial recognition may also be used to identify and authenticate a user. In some embodiments, the sensors 172 or sensor array 170 may be configured to biometrically identify the user based on physiological data obtained from the user. In some embodiments, the sensors 172 or sensor array 170 may be configured to collect information about muscle activity in order to analyze gestures, enabling the use of gestures to interact with the user device 100. Particular detected gestures may be associated with or cause particular functionality or interaction with the device 100 and associated software systems. For example, in one exemplary embodiment sensors 172 or sensor array 170 may be configured to detect the gesture “extended forefinger” which causes activation of the video camera, such a side camera, or causes operation of scanner software (such as a text/barcode scanner). In another exemplary embodiment, sensors 172 or sensor array 170 may be configured to detect the gesture “clenched hand” which causes activation of the mute mode in connection with an incoming telephone call. These embodiments merely illustrate the capability of these aspects of the invention and many other embodiments are possible as well.

While the embodiments 100A, 100B depicted in FIGS. 1a-1e depict specific configurations of a wearable user device 100, these embodiments are only illustrative examples of wearable user devices 100 within the scope and spirit of the present invention. Accordingly, in further embodiments, various components or structures of a user device 100, compared to the embodiments 100A, 100B may be absent, present in plurality, disposed in different places, composed of different materials, or the like.

In various embodiments, there may be one or more camera disposed on any suitable portion of the user device 100. For example, there may be one or more camera on the first and/or second arm 110, 115, including one or more camera disposed on the internal portion 174 within the cavity 120. In some embodiments, one or more camera may be used for sensing and may comprise a portion of a sensor array 170. In embodiments having a plurality of cameras, the cameras may be the same or different.

Similarly, components such as the speaker 135 and microphone 162 may be present on any suitable portion of the user device 100 and either may be present in a plurality in some embodiments. One or more microphone 162 or speaker 135 may be disposed on the internal portion 174 within the cavity 120. In some embodiments, one or more microphone 162 or speaker 135 may be used for sensing and may comprise a portion of a sensor array 170. In embodiments having a plurality of microphones or speakers, the microphones or speakers may be the same or different. A suitable microphone 162 or speaker 135 may include a device that can transmit or sense sound of various frequencies including sonic, supersonic and sub-sonic frequencies.

Components such as the port 150, media-card slot 155 or communication plug 168 may be disposed on any suitable portion of the user device 100 and any may be present in a plurality in some embodiments. Examples of a suitable port 150 and communication plug 168 may include male or female Universal Serial Bus (USB), Ethernet, IEEE 1394, parallel, serial, IBM Personal System/2 (PS/2), Video Graphics Array (VGA), phone connector, RCA, or the like. The media-card slot 155 may be configured for use with any suitable memory system including a Secure Digital (SD) card, a CompactFlash (CF-I) card, MultiMedia (MMC) card, SmartMedia card, or the like without limitation. In some embodiments, the media card slot 155 may be configured for a Subscriber Identification Module Card (SIM Card), or the like.

The user device 100 may comprise one or more sensor array 170, which each may comprise one or more sensor 172. A sensor array 170 or sensor 172 may be disposed on any suitable portion of the user device 100. In various embodiments, it may be desirable for sensors 172 to be disposed on the internal portion 174 of the cavity so that sensors 172 may contact the arm 101 of a user. In various embodiments, it may be desirable for sensors 172 to be disposed around the diameter of the user device 100, for example in an exemplary embodiment, six electrodes disposed around the diameter of a wristband embodiment of user device 100. As discussed in more detail herein, sensors 172 may be used to sense a physical quantity or condition associated with a user. Such sensing may be used to determine a physiological state or condition of user as further described herein. In some embodiments, sensors may also be configured to sense quantities or conditions of other systems, environments, or the like.

Sensors 172 or sensor arrays 170 may be any suitable type, and may used for one or more suitable sensing purpose. For example, sensors 172 or sensor arrays 170 may include a gyroscope, accelerometer, compass, luminance sensor, body temperature sensor, infrared sensor, pulse-meter, high frequency electrodes, emo-sensor, displacement sensor, linear acceleration sensor, angular acceleration sensor, ambient temperature sensor, ambient light sensor, microphone, camera, magnetomer, barometer, muscle strain gauge, brain wave sensor, blood pressure sensor, skin resistance sensor, infrared temperature sensor, impedance plethysmography sensor, photoplethysmograph sensor, radio receiver, or the like. In some embodiments, a sensor 172 or sensor array 170 need not be disposed on the user device 100, and such sensors may be operably connected to the device 100 via a wired or wireless network.

Additionally, while a user device 100 is shown being worn on the arm 101 of a user. The user device 100 may be adapted for use on various body parts of human or non-human users, including a head, neck, leg, torso, foot, hand, finger, toe or the like. Additionally, in some embodiments, the user device 100 is not configured to be worn.

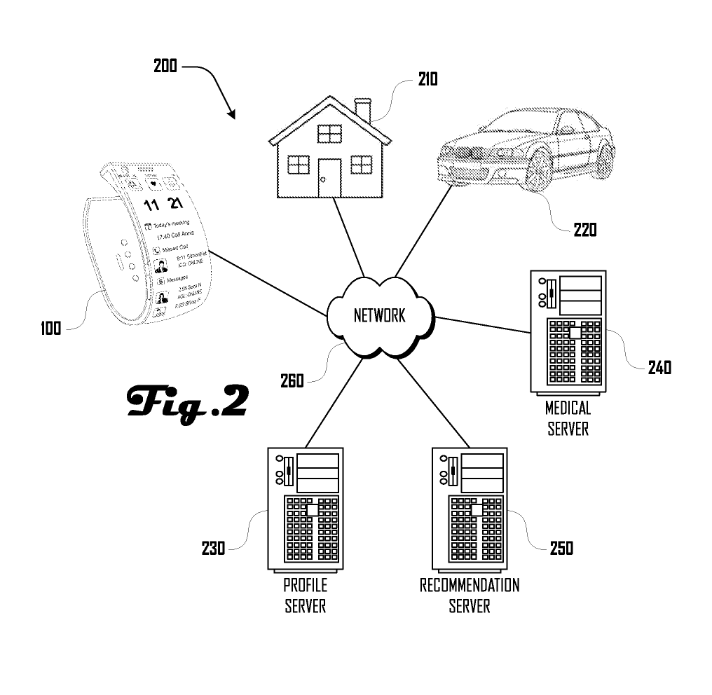

Turning to FIG. 2, an exemplary system 200 is shown that includes a user device 100, a building system 210, a vehicle system 220, a profile server 230, a medical server 240, and a recommendation server 250, which are all operably connected via a network 260.

Additionally, the servers 230, 240, 250 may be any suitable device, may comprise a plurality of devices, or may be a cloud-based data storage system. As discussed in further detail herein, servers 230, 240, 250 may be operated by the same company or group, or may be operated by different companies or groups.

In various embodiments, the network 260 may comprise one or more suitable wireless or wired networks, including the Internet, a local-area network (LAN), a wide-area network (WAN), or the like.

The building system 210 may include a home-automation system, one or more devices associated with a building network, or the like. The vehicle system 220 may include a vehicle computer, network or one or more devices associated with a vehicle. Some embodiments may include a plurality of user devices 100, servers 230, 240, 250 or systems 210, 220. In some embodiments, any of the servers 230, 240, 250 or systems 210, 220 may be absent or combined.

In addition to the functionalities described herein, the user device 100 may have some or all of the functionalities of devices such as a smart-phone, tablet computer, gaming device, laptop computer, server, or the like. Accordingly, the user device 100 may have one or more processor and memory, which may be operable to store and execute any desirable operating system, software, media or the like.

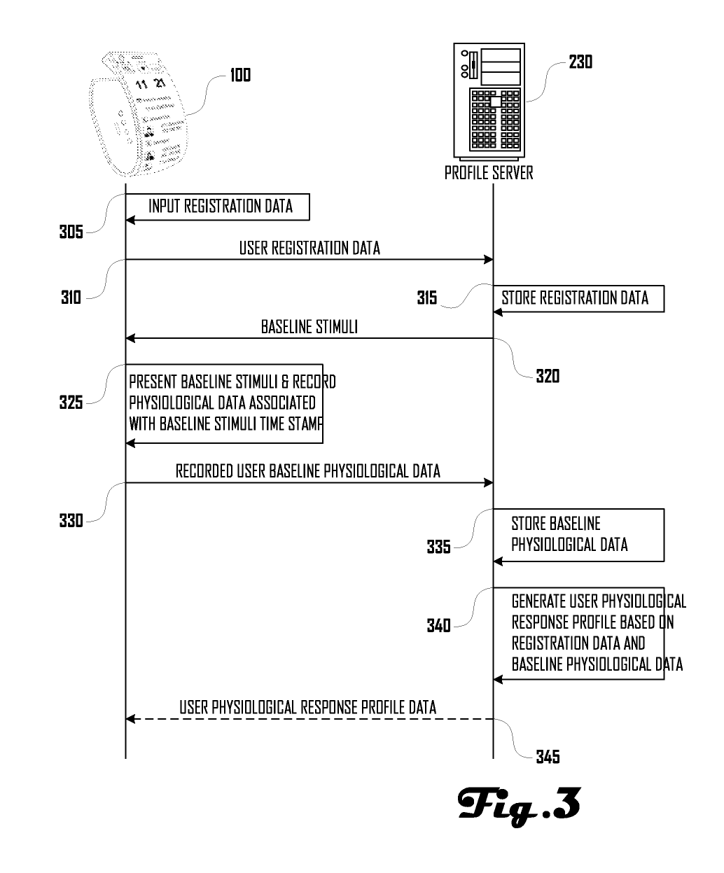

Various embodiments include functionalities of a user device 100 associated with sensing a physiological state of a user, including emotional state, and using this data compared to various stimuli to generate a physiological profile for a user; to determine the user's response to media content (e.g., movies, music or the like); and to provide personalized content recommendations based on the physiological and/or emotional state of the user. FIGS. 3-8 depict examples of data flow paths, methods and the like that may provide for such functionalities.

Turning to FIG. 3, an exemplary data-flow diagram is depicted which illustrates communications of an embodiment of generating a user physiological response profile. The data flow begins, at 305, where registration data is input at the user device 100 and sent to the profile server, at 310, where the registration data is stored, at 315. For example, registration data may include basic bibliographical, contact and identifying information about a user including a name, gender, age, a user name, a mailing address, an e-mail address, a phone number, a user account identifier, or the like. In some embodiments, it may be desirable to obtain more information about a user, which may be used to generate a physiological profile. For example, in some embodiments, user registration data may also include current and historical data regarding race, ethnicity, nationality, personality traits, medical data, relationship status, political affiliation, education, profession, income, entertainment preferences, food preferences, family structure, sexual preference, emotional maturity, hobbies, weight, height, and the like.

Baseline stimuli is sent to the user device 100, at 320, and baseline stimuli is presented and physiological data associated with a baseline stimuli time stamp is recorded at 325. The recorded user baseline physiological data is sent to the profile server 230, at 330, where the baseline physiological data is stored, at 335. A user physiological response profile based on registration data and baseline physiological data is generated, at 340.

In various embodiments, baseline stimuli may be any suitable presentation that is designed to generate, trigger or elicit an emotional or physiological response from a user that views and/or listens to the stimuli. In some embodiments, the stimuli may comprise a portion of a television show, a portion of a movie, a portion of a song, one or more image, text, or the like. For example, in some embodiments, the baseline stimuli may include clips from movies that are designed to generate, trigger or elicit a response of fear, anger, joy, sadness, confusion, pleasure, sexual arousal, dislike, nostalgia, love, compassion, excitement, disgust, tension, a neutral emotive state, or the like.

In some embodiments, portions, aspects, or presentation order of baseline stimuli may be selected based on received user registration data. User registration data may be used to determine what stimuli would cause the greatest emotional response, or used to select video clips that are intended to generate, trigger or elicit a desired response. For example, if user registration data indicates that the user is a heterosexual male, stimuli containing female subjects may be selected to generate, trigger or elicit a response of sexual arousal. In contrast, if user registration data indicates that the user is a heterosexual female, stimuli containing male subjects may be selected to generate, trigger or elicit a response of sexual arousal. Accordingly, baseline stimuli may be tailored to the individual user in some embodiments.

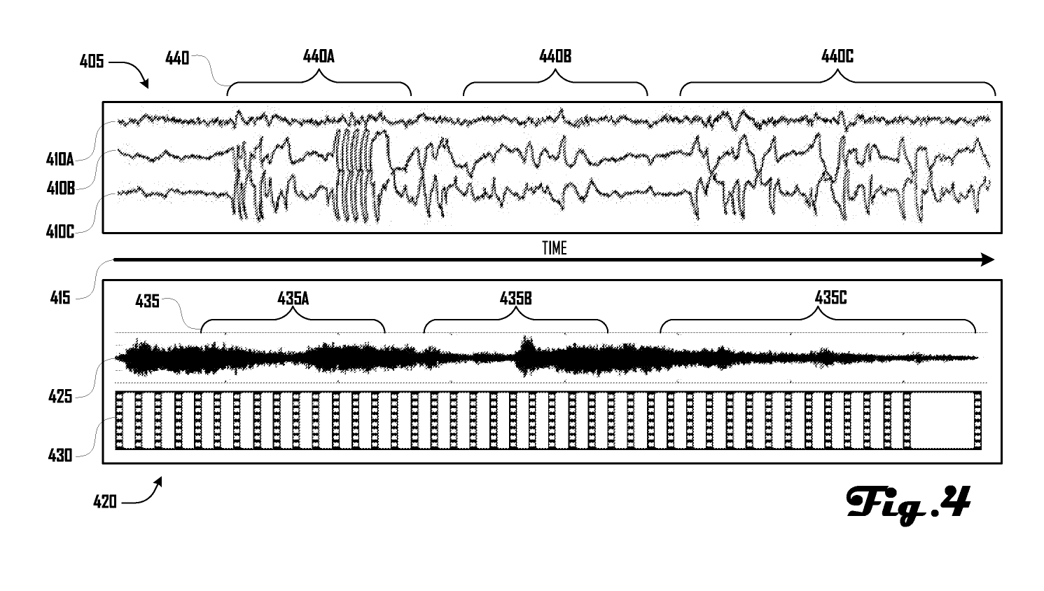

When viewing or listening to baseline stimuli, data is obtained from one or more sensor 172 or sensor array 170 and associated in time with the baseline stimuli presentation. Such time association or synchronization is illustrated in FIG. 4, and is further discussed herein in more detail.

Generating a user physiological profile may include associating a signature user physiological response with a plurality of emotional or other user states. For example, when a user is exposed to a stimulus that generates, triggers or elicits a fear response, physiological data obtained by the one or more sensor 172 or sensor array 170 may used to define a user signature for a fear response. Accordingly, when a similar signature, pattern, or the like is observed, a determination can be made that the user is experiencing a fear response. Training or generating a user physiological response profile thereby may allow for sensing one or more emotional or physiological state of a user.

Computer learning techniques for building, generating and training a user physiological response profile include linear regression, logistic regression, neural networks, support vector machines, and the like. One or more supervised or unsupervised computer learning algorithm may be applied to training or generating a user physiological response profile.

Returning to the data flow of FIG. 3, in a communication, at 345, user physiological response profile data may be sent to the user device 100. Accordingly, in some embodiments, the user device 100 may be operable to interpret physiological data or other data sensed by the user device 100 and determine one or more user physiological state or emotional state based on the user physiological response profile stored on the user device 100. However, in some embodiments, such determinations and correlations may be performed by the profile server 230 or other suitable device.

Turning now to FIG. 4, an exemplary depiction of synchronized physiological data and media content data is depicted in accordance with an embodiment. FIG. 4 shows a depiction of a set of data or signals 405 obtained by sensors 172 or a sensor array 170 (i.e., a first, second and third signal 410A, 410B, 410C). The signals 405 are associated with a time signature indicated by the time line 415. Although three signals are shown in this example, in some embodiments there may one or any plurality of signals obtained from a user device 100. Signals may be associated with user physiological data or may include other data such as environmental conditions or the like.

Media content 420 is also associated with or synchronized with the time signature line 415 and with the set of signals 405. The media content 420 includes a set of frames 430 and audio content 425. In some embodiments, the media content may have trigger sections 435 that are associated with an emotional or physiological trigger. For example, first, second and third trigger sections 435A, 435B, 435C are show in FIG. 4 as an example.

Referring to the example of baseline stimuli discussed in relation to FIG. 3 above, the trigger sections 435 may be associated with video clips that are designed to generate, trigger or elicit an emotional or physiological response in a user. For example, the first trigger section 435A may be associated with scary movie clip designed to generate, trigger or elicit a fear response from a user.

When generating a physiological response profile as discussed above, response portions 440 of the signals 405 may be correlated with the emotion or physiological response associated with a given trigger section 435. For example response portion 440A may be associated with response trigger section 435A, and therefore the portion of the signals 405 within response portion 440A correspond to a user response of fear. Accordingly, a physiological response profile may correlate a signature or pattern of signals with a given emotional or physiological response.

In contrast, as further described herein, user signals 405 may be used to define and identify trigger sections 435 in media content 420. Where a physiological response profile is available for a given user, the signals 405 can be processed or interpreted to identify portions that correspond to a given emotional response. For example, processing of the signals 405 may identify response portion 440A as a response portion associated with a user response of fear. Accordingly, trigger section 435A may be identified as being a portion of the media content 420 that is scary.

As shown in FIG. 4, trigger sections 435 and response portions 440 may not be the same length in time and may not be synchronized in time. This may be because some emotional or physiological responses are delayed from the time that a user receives a given stimulus. Time delays of various emotional or physiological responses may vary by emotion or physiological state, by user, or by various other factors. Additionally, while the example of FIG. 4 depicts media content 420 having an audio portion 425, and video portion 430, in various embodiments, user stimuli may include only audio stimuli, only video stimuli, or may include other stimuli which may or may not be digital media. For example, stimuli may include olfactory or tactile stimulation or may include spontaneous stimuli such as a live ballet, sunset, kiss, or the like.

In still further embodiments, and as further discussed herein, where trigger sections 435 are known for a plurality of media content 420 (e.g., for a plurality of movies), determining response portions 440 of a user signal can be used to determine the identity of the media content 420 that a user is viewing. For example, a given piece of media content 420 may have a signature sequential set of trigger sections 435, and where a user is experiencing response portions 440 that correspond to a given piece of media content, a determination can be made that the user is viewing that media content 420, and a determination may be made as to what portion of the media content 420 is being viewed.

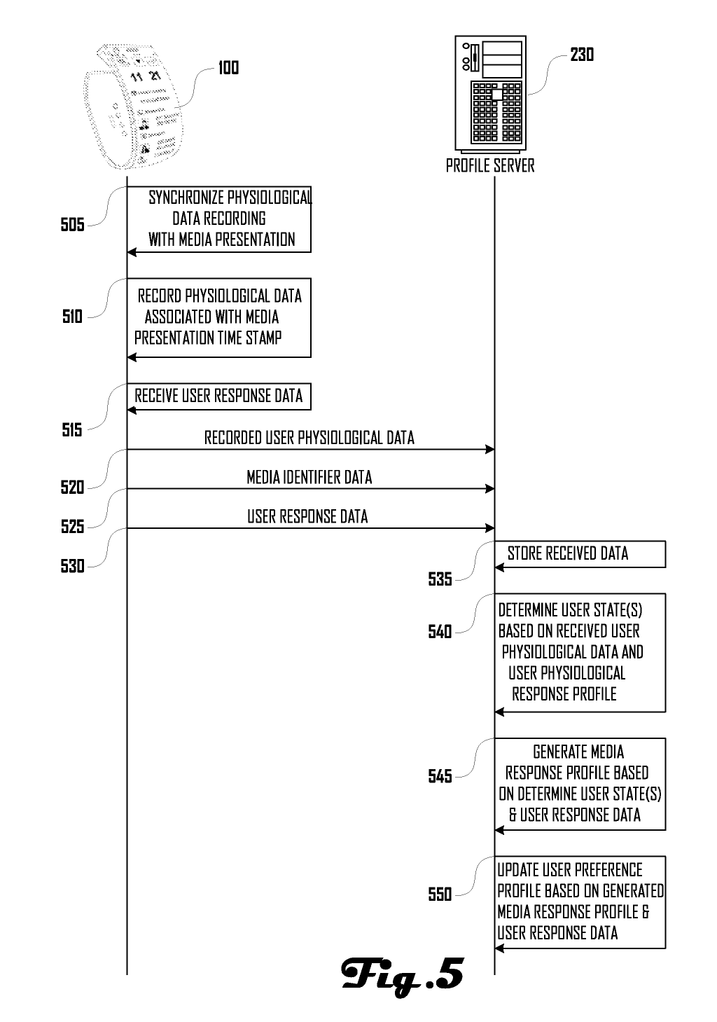

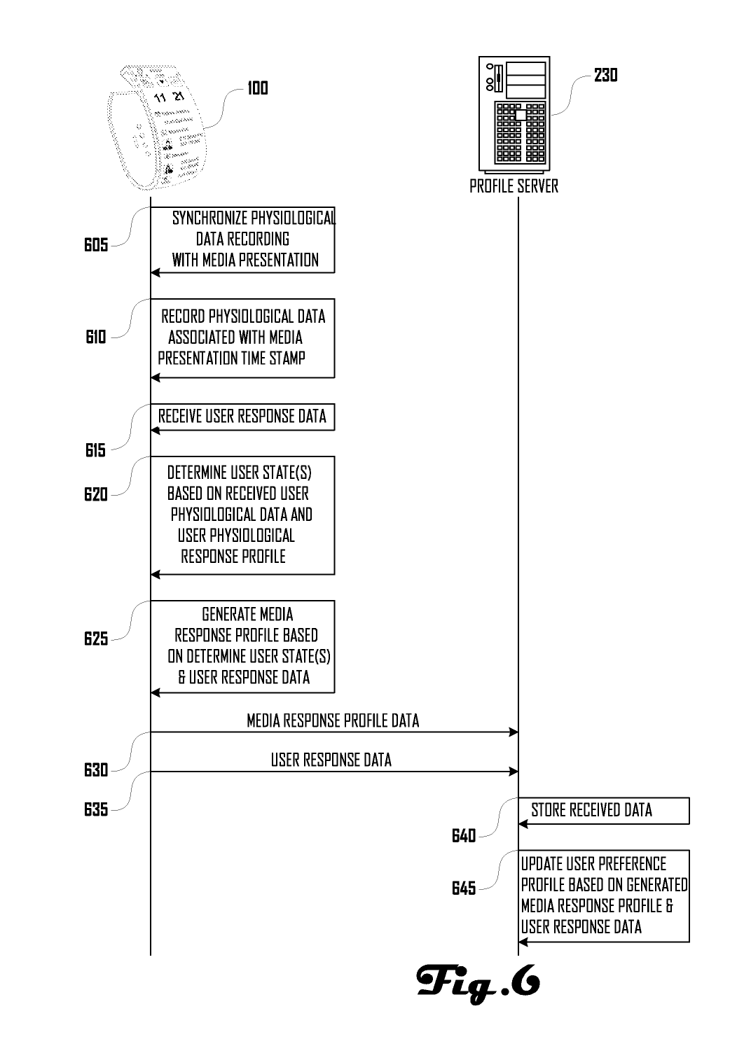

Turning to FIG. 5, an exemplary data-flow diagram is depicted illustrating communications of an embodiment of generating a media response profile. The data flow begins at 505, where physiological data recording is synchronized with a media presentation and physiological data associated with a media presentation time stamp is recorded, at 510. Synchronization of a media presentation may be as described in relation to FIG. 4. In some embodiments, the media presentation may presented on the user device 100, may be projected from the user device 100, or may be streamed from the user device 100 to a remote display. In further embodiments, where the user device 100 is not directly associated with the presentation of media content (e.g., at a public movie theatre) synchronization may occur by determining a time associated with a media presentation based on sensed audio or visual data obtained by the user device 100, or the user device 100 may receive a time stamp, synchronizing data, or the like from a device presenting or associated with presentation of the media presentation.

Returning to the data flow, user response data is received at 515. In various embodiments, it may be desirable to obtain user response data to assist in interpreting user physiological data. For example, a user may provide feedback regarding the media presentation at defined points during the media presentation, in real-time during the media presentation, or at the end of a media presentation. User feedback may be important to determining user preferences and interpreting received user signals 405 (FIG. 4).

For example, if a fear response or emotion is detected, it may be desirable to know the user's preference regarding this emotional response. Some users may enjoy scary movies, whereas others may not enjoy scary movies. Moreover, a user may enjoy certain scary portions of a movie, but may not enjoy other scary portions. Therefore, user enjoyment of a given emotional response may be necessary for interpreting related user responses, user signals 405, and the like.

Similarly, where a given emotional response is expected during a portion of a media presentation, it may be desirable to have user feedback regarding the user physiological state or emotional state that the user experiences during that portion of the media presentation. For example, during the culmination of a mystery movie, a user may experience confusion, satisfaction or may be disengaged. Receiving user feedback or a response regarding the user's experience during that portion of the movie may be desirable for movie producers, for creating a user preference profile, or the like. For example, if many users experiencing a portion of a movie do not have a desired reaction, the movie can be changed to provide the desired emotional or physiological response. Additionally, it may be desirable to disregard portions of user signals 405 received because they are not relevant to the media presentation. For example, the user may be distracted, thinking about something other than the media presentation, talking with a friend, or may be away from the media presentation using the restroom or the like.

Returning to the data flow of FIG. 5, the recorded user physiological data, media identifier data, and user response data are sent to the profile server 230, at 520, 525, and 530, where the data is stored at 535. One or more user physiological states and/or emotional states are determined based on the physiological data and the user physiological response profile, at 540. Such determining is discussed above in relation to FIG. 4. For example, response portion 440 may be determined.

At 545, a media response profile is generated based on one or more determined user emotional or physiological states and based on the user response profile. Such a generation is discussed above in relation to FIG. 4. For example, one or more trigger section 435 may be identified in relation to given media content. Additionally, user response data may be used to disregard or re-interpret a determined physiological or emotional response in a media response profile, or user response data may incorporated as a portion of a media response profile. For example, the media response profile may include a plurality of trigger sections 435 and associated indications of whether the user had a positive or negative response to the triggered emotional or physiological response.

In some embodiments a response media profile may be aggregate and include or be generated based on a plurality of obtained user physiological and user response data. This may be desirable because each user may have a unique response to a given piece of media content, and having a large sample size of user physiological and user response data may better reflect and predict how an average consumer of the media content may respond to the content.

Returning to the data flow of FIG. 5, a user preference profile is updated based on the generated media response profile and the user response data. A user response profile may include data regarding or related to any preference of a user. For example, regarding movie content, a preference profile may relate to a user's preference of movie genres, specific movies, specific actors, themes, time periods, release dates, types of movie scenes, or the like. Similar preferences may be applied to other types of media content. In some embodiments, user preference data may be obtained from or comprise user preference data from an existing user preference profile. For example, preference profiles from applications such as Netflix, Pandora, Hulu, Pinterest, Google, or the like, may be used as a source of user preference data.

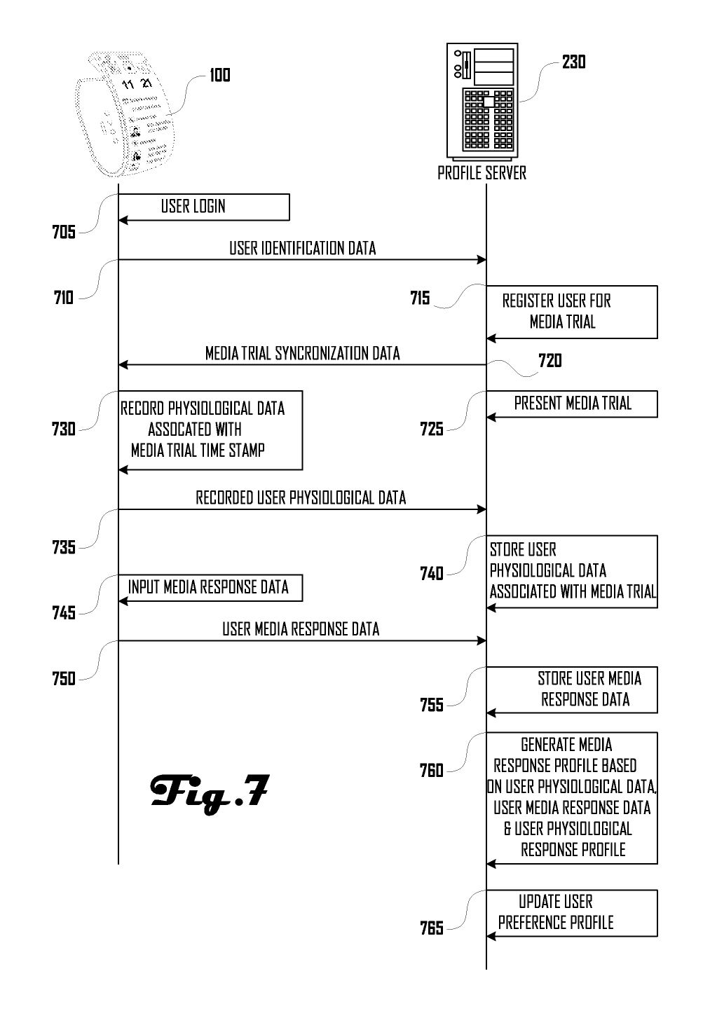

Although FIG. 5 shows specific processing being performed by user device 100 or the profile server 230, in various embodiments any of the processing steps may be performed by one or both of the user device 100, profile server 230 or other suitable device. For example, FIG. 6 depicts an alternative embodiment of generating a media response profile, wherein additional processing occurs at the user device 100. In this embodiment, a user physiological response profile is stored on the user device 100 and used for various processing.

The data flow of FIG. 6 begins, at 605, where physiological data recording is synchronized with a media presentation and, at 610, physiological data is recorded associated with a media presentation time stamp. At 615, user response data is received, and at 620, one or more user physiological or emotional states are determined based on received user physiological data and the user physiological response profile. At 625, a media response profile is generated based on the one or more determined user emotional or physiological states and based on user response data. Media response profile data and user response data is sent to the profile server 230, at 630 and 635, where the data is stored, at 640. A user preference profile is updated based on the generated media response profile and based on the user response data, at 645.

In some embodiments, one or a plurality of user devices 100 may be used to conduct trials of media content to determine how users respond to a given piece of media content. For example, a plurality of users may watch a movie together, a plurality of users may watch a television program at their respective homes, or a plurality of listeners of a radio station may listen to audio content in separate locations.

Turning to FIG. 7, and exemplary data-flow diagram illustrating communications of a further embodiment of generating a media response profile is depicted. The data flow begins at 705, where a user logs, in and user identification data is sent to the profile server 230, at 710, where the user is registered for a media trial, at 715.

At 720, media trial synchronization data is sent to the user device 100 and the media trial presentation begins, at 725. Physiological data is recorded associated with a media trial time stamp, at 730. At 735, recorded user physiological data is sent to the profile server 230 where the user physiological data associated with the media trial is stored, at 740. Media response data is obtained from the user device 100, at 745 and user media response data is sent to the profile server, at 750, where the user media response data is stored, at 755. At 760, a media response profile is generated based on user physiological data, user media response data, and the user physiological response profile. A user preference profile is updated, at 765, as discussed herein.

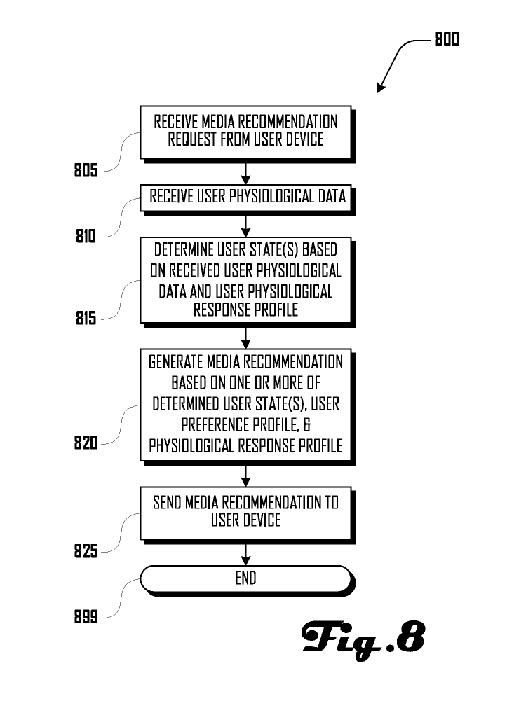

A plurality of media response profiles, each respectively associated with a given piece of media content, may be used to provide media content recommendations to a user. FIG. 8 is an exemplary flow chart illustrating a method 800 of generating a media content recommendation, which may be performed by the recommendation server 250, or another suitable device or server. The method 800 begins in block 805, where a media recommendation request is received from a user device 100, and in block 810, user physiological data is received from the user device 100. In block 815, one or more user physiological or emotional states are determined based on the received user physiological data and the user physiological response profile.

In block 820, a media recommendation is generated based on one or more of the determined physiological or emotional states; based on the user preference profile; and based on the physiological response profile. For example, where a determined user state includes sadness, an up-beat or happy song or movie can be recommended to the user to improve the user's mood. The song or movie can also be selected based on specific songs or movies that the user has an affinity for based on the user preference profile; based on songs or moves similar to songs or movies that the user has an affinity for based on the user preference profile; or based on songs or movies that have historically improved the user's mood based on physiological or emotional states identified while the user was consuming the audio or movie.

In some embodiments, media content playlists may be selected to regulate and vary a user's emotional state to maintain interest and engagement. For example, exciting songs may be played for the user, and when the user's excitement level is determined to have peaked, then down-tempo songs may be played to depress the user's emotional state. When the user's emotional state has reached a next desired state, the other songs can be selected to change the user's mood again.

While some embodiments may provide recommendations personalized for a single user associated with a user device 100, some embodiments provide for recommendations based on one or more determined physiological or emotional states of a plurality of users. Accordingly, a plurality of user devices 100 may be paired or grouped for various purposes. For example, a pair of users on a date can have music selected based on their respective and/or collective physiological or emotional states. Additionally, a plurality of dancers at a party can have music selected for them based on individual or collective user preference profiles and/or based on detected physiological or emotional states of the group of users, either individually or collectively. Certain songs may be played to get certain users more engaged and energized, or certain songs may be played to alter the mood of the crowd as a whole.

Media content is only one example of a subject of recommendations, response profiling, preference profiling, and the like. In further embodiments, restaurants, activities, travel destinations, consumer products, investments, business plans, food, websites, games, exercise routines, medications, sleep routines, dating partners, gifts, or the like may be the subject of response profiling and user recommendations.

Various embodiments of a user device 100 may include near field communication (NFC), radio-frequency identification (RFID), or the like. Such components may provide for numerous applications including e-purse payment systems, security key functionality and the like.

Further embodiments of a user device 100 are configured to operably communicate with a vehicle system 220 and provide various functionalities. The user device 100 may be operable to play selected audio media via a vehicle audio system, and may be configured to select audio or provide alerts based on sensed or determined user physiological data. For example, if a determination is made that the driving user is sleepy or falling asleep, the user device 100 may select audio that awakens the user, provide an audio alert, or provide a recommendation to rest or sleep.

Some embodiments of the user device 100 may include a projector, which may project images in a desired direction on various surfaces. In a vehicle context, such a projector may generate a heads-up display on the windshield of the vehicle, which may provide a navigation display, vehicle information display, media display, or the like.

The user device 100 may also be operable to communicate with a building system 210 (FIG. 2) and be operable to control various aspects of a building environment including HVAC systems, air conditioning, heating, lights, alarm systems, sprinkler systems, or the like. The user device 100 may also communicate with and control various appliances and devices within a building, including a television, entertainment system, gaming device, refrigerator, oven, clock, or the like. Such communication may be via a home network or automation system, or may be directly with the device via a local connection such as Bluetooth, RFID, NFC or via WiFi, or may be via the Internet, or the like.

Any suitable feature or setting of a vehicle system 220, building system 210 or devices therein may be automatically changed or affected by a detected physiological or emotional state of a user. For example, where a determination is made that the user is in an agitated emotional state, ambient temperature within a room or building may be changed along with ambient lighting to change the emotional state of the user. Similarly, where a user is determined to be cold or warm, the ambient temperature of a room or building may be changed to generate a desirable temperature for the user.

Additionally, settings of a vehicle system 220, building system 210, or devices therein may be changed based on the identity of users in a location, location of users within a building or room, proximity to a given device or system component, preferences of a user, a detected user state, or the like. In various embodiments, access control to devices, functionalities, windows or doors may be based on user identity. This may be desirable for functionalities such as child-protection. For example, where a child is present in a vehicle or building proximate to a door or window, the door or window may automatically be set to a child-lock setting, whereas adults proximate to a door or window would have full control over door or window locking and control mechanisms.

Similarly, various devices may be selectively locked or provided with selectively reduced functionality based on user identity. For example, devices such as heating/cooling systems, media devices, or the like may be restricted to only certain users such as adults, company employees, registered users, family members, or other selectively authorized users. In some embodiments, a NFC or RFID tag may be used to determine user identity.

In various embodiments, settings of various devices may be customized based on user identity, preference, and determined physiological or emotional state. For example, a user picking up a television controller may be identified via a NFC or RFID tag present in the user device 100, and default settings, menu configurations, audio settings, display settings, channel access or the like may be customized based on the user's identity, access permissions, and emotional or physiological state.

In still further embodiments, the user device 100 may be configured to provide medical or health-care functionalities. In addition to detecting, determining and sensing user states such as emotional states, the user device 100 may also be configured to detect, determine or sense physiological states that relate to health of the user. For example, physiological states such as heart rate, heart rhythm, blood pressure, sleep state, blood-oxygen saturation, and the like may be sensed, determined or detected by sensors 172 or sensor arrays 170. Such physiological data can be stored on the user device 100 and/or communicated to the medical server 240 (FIG. 2). Data provided to the medical server can be applied to health records, used to determine health and body patterns of a user, used to diagnose disease in a user, provide dietary, exercise or medication recommendations to a user, or provide an alert to the user, health care providers or the user's family if the user is detected having a medical emergency. Moreover, tracking a user's emotional and psychological states may be used by mental health providers or the like. Similarly, physiological data may be used for sports and workout purposes. For example, sensed physiological states can be used to provide personalized workout routines including physical fitness games.

Sensed emotional and physiological states may also be broadcast in various ways or used to modify settings of the user device 100. For example, an emotional or physiological state identified or determined by the user device 100 may be used as part of a status update on a social network (e.g., Facebook, Twitter, Skype, or the like).

In various embodiments, the user device 100 may identify physiological states related to sleep. For example, the user device 100 may detect that a user is sleepy, sleeping, waking up or the like. Additionally, the user device 100 may detect various portions of a sleep cycle including non-rapid eye movement states (NREM stages 1-3) and a rapid eye movement (REM) sleep state. Other physiological or emotional states may also be detected in relation to a sleeping state and may be used to determine a user dream experience.

User physiological states related to sleep may be determined in various ways. For example, the user device 100 being worn by a user may obtain a set of signals 405 (FIG. 4) from sensors 172 or sensor array 170 and compare the signals 405 to one or more set of previously obtained signals 405 corresponding to the user (or other users) while sleeping and make a determination of whether there is sufficient correspondence to indicate that the user is sleeping.

Detecting and determining physiological or emotional states associated with sleeping may be desirable because it can provide more efficient and restful sleep for a user. For example, where a determination is made that a user is sleepy or entering a sleep state, settings or other aspects of the user device 100 and/or other devices or systems may be changed accordingly. For example, where the user is at home, a home automation system 210 (FIG. 2) may be configured to reduce the intensity of ambient lights, reduce the volume of media or audio presentations, and change the cooling or heating of the home to better accommodate sleep. In contrast, in a vehicle setting, a vehicle system 220 may be configured to awaken a driver when a sleepy or sleeping state is determined.

Determination of sleep, dream, or other user states may be used to generate restful and efficient sleep experiences for a user. For example, where a determination is made that a user is having a nightmare or other undesirable sleep experience that negatively effects sleep, the user device 100 may awake the user via an alert or the like. Similarly, where a determination is made that the use has achieved a sufficiently restful amount of sleep, the user device 100 may be configured to awake the user via an alert or the like.

In another example, where a sleeping physiological state is identified, telephone functions of the user device 100 may be deactivated, the phone may be set to a silent ringer, calls may be forwarded, or calls may be set to go directly to voicemail. Additionally, calls may be selectively received or sent to voicemail (e.g., accept calls from a spouse, but reject all calls from telemarketers, unknown numbers, and all other contacts). Similarly, other alerts may be selectively delayed or set to silent. Accordingly, in various embodiments, the user device 100 may be configured to not disturb or selectively disturb a user while the user is determined as being in a sleeping state.

A determination of a sleeping physiological state may also be used change or update a status on a social network, email program, chat program or the like. For example, when a user wearing the user device 100 sleeps, the user device 100 may send a signal to social networks, chat programs, (e.g., Skype, ICQ, or Facebook) and may send a notification to a list of contacts. Accordingly, in some embodiments a user's contacts may see that the owner is asleep or that the user is inactive on a given social network, email program, chat program or the like. In some embodiments, such a notification may be the same as a notification that occurs when a user is inactive, away, logged off, or the like. In some embodiments, a sleep or mood “status update” may be provided to or integrated into social networks or similar online applications or services. Because the user device 100 may have persistent or frequent interaction with the user's physiological or emotional parameters, the device provides for new standards of informing users of social networks and similar online applications or services of the mood, sleep state, waking state or other physiological or emotional state of a user wearing user device 100. Associated “status update” categories and modes (for example “sleep status,” “mood status” etc.) may be defined in relation to such mood, sleep state, physiological or emotional state information about a user wearing user device 100. In some embodiments, such a notification may be a separate notification indicating that the user is sleeping, asleep, in bed, or the like.

Accordingly, from the foregoing it will be appreciated that, although specific embodiments have been described herein for purposes of illustration, various modifications may be made without deviating from the spirit and scope of the disclosure. Furthermore, where an alternative is disclosed for a particular embodiment, this alternative may also apply to other embodiments even if not specifically stated.

What is claimed is:

1. A wearable user device comprising:
a device body defining:
a first arm extending from a central body portion to a first-arm end and having an external first-arm face and an internal first-arm face on opposing sides of the first arm;
a second arm extending from the central body portion to a second-arm end and having an external second-arm face and an internal second-arm face on opposing sides of the second arm; and
a concave cavity defined by the first and second arm and the central portion and configured to be worn on an elongated part of a body;
a first display disposed on a portion of the external first-arm face; and
a sensor array disposed on one or both of the internal first-arm and second-arm faces configured to contact the elongated part of a body when the user device is worn.

2. The wearable user device of claim 1, further comprising a second display disposed on a portion of the external second-arm face.

3. The wearable user device of claim 1, further comprising:
a first-arm end face substantially perpendicular to the external first-arm face; and
a first camera disposed on the first-arm end face.

4. The wearable user device of claim 3, further comprising a second camera disposed on the external first-arm face.

5. The wearable user device of claim 3, further comprising a communication port and a memory card slot disposed below a hatch on the first-arm end face.

6. The wearable user device of claim 1, further comprising:
a communication connector rotatably disposed on the second-arm end and operable to rotate from a stored position to an extended position.

7. The wearable user device of claim 1, wherein the device body is substantially C-shaped.

8. The wearable user device of claim 1 further comprising a hinge that extends along a width of the device body at the central body portion and configured to rotatably couple the first and second arm such that the first and second arm are operable to rotate toward and away from each other.

9. The wearable user device of claim 1 further comprising a hinge that extends along a width of the device body along a portion of the second arm and defining a rotatable second-arm tip at an end of the second arm.

10. The wearable user device of claim 1 further comprising:
a first hinge that extends along a width of the device body at the central body portion and configured to rotatably couple the first and second arm such that the first and second arm are operable to rotate toward and away from each other, and
a second hinge that extends along a width of the device body along a portion of the second arm and defining a rotatable second-arm tip at an end of the second arm,
wherein the hinges are configured to change the size of the concave cavity by rotatably changing the position of the first and second arm and the second-arm tip.

11. A method of providing a media content recommendation comprising:
obtaining user registration data;
obtaining user baseline physiological data synchronized with a baseline stimuli;
generating a user physiological response profile based on the user registration data and the user baseline physiological response data;
obtaining user preference data;
generating a user preference profile based at least on the user preference data;
obtaining a media content recommendation request;
obtaining physiological data associated with the content recommendation request;
determining one or more user state based on the physiological data associated with the content recommendation request and the user physiological response profile; and
generating a media content recommendation based on the determined one or more user state and the user preference profile.

12. The method of claim 11, wherein the baseline stimuli comprises a series of at least one of audio and visual stimuli, the baseline stimuli comprising a plurality of trigger sections.

13. The method of claim 12, wherein each of the plurality of trigger sections are configured to trigger at least one of an emotional and physiological response in a user.

14. The method of claim 11, wherein user baseline physiological data and physiological data associated with the content recommendation request comprises a plurality of user signals obtained from a sensor array worn by a user.

15. The method of claim 11, further comprising presenting baseline stimuli to a user associated with the user registration data and recording physiological data associated with the user and synchronized with the presentation.

16. The method of claim 11, wherein the one or more user state is an emotional state.

17. A method of generating a media response profile comprising:
obtaining user registration data from a plurality of users;
obtaining, for each of the users, user baseline physiological data synchronized with baseline stimuli;
generating, for each of the users, a user physiological response profile based on respective user registration data and user baseline physiological response data;
presenting a media presentation to a portion of the plurality of users and obtaining user physiological data from each of the portion of users that is synchronized with the media presentation;
generating a media response profile associated with the media presentation based on respective user physiological data and user physiological response profiles.

18. The method of claim 17, further comprising obtaining media response data associated with the media presentation from the portion of the plurality of users, and wherein the generating a media response profile is further based on the media response data.

19. The method of claim 17, further comprising obtaining user preference data from the portion of the plurality of users, and wherein the generating a media response profile is further based on the user preference data.

20. The method of claim 17 further comprising determining a plurality of user states for each of the portion of the plurality of users based on respective user physiological data and user physiological response profiles, the determined user states each corresponding to a portion of the media presentation.
